(19) United States
(12) Patent Application Publication
(10) Pub. No.: US 2010/0110753 A1
(43) Pub. Date: May 6, 2010

(54) Ferroelectric Memory Cell Arrays and Method of Operating the Same

(75) Inventors: Stefan Slesazeck, Dresden (DE); Rolf Weis, Dresden (DE); Stefan Jakschik, Leuven (BE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 12/262,830

(22) Filed: Oct. 31, 2008

(51) Int. Cl. G11C 11/22; G11C 7/00; G11C 11/34; H01L 21/20

(52) U.S. Cl. 365/145; 365/189.011; 365/191; 365/182; 365/174; 438/486; 257/E21.09

(57) ABSTRACT

An integrated circuit includes a plurality of switching devices, wherein each device includes a gate dielectric capable of assuming at least a first and a second polarization state. The integrated circuit further includes an address circuit configured to control bit lines electrically coupled to first load regions of a load path of the switching devices and a word line electrically coupled to gate electrodes of the switching devices. The address circuit is configured to control a write cycle such that a first voltage is induced at the gate dielectrics of selected ones of the switching devices and a second voltage is induced at the gate dielectrics of non-selected ones of the switching devices. The first voltage suffices to switch the gate dielectrics of the selected devices from the first to the second polarization state and the second voltage does not suffice to switch the gate dielectrics of the non-selected devices.

### BACKGROUND

In ferroelectric random access memories (FeRAMs), data information is represented by a polarization state of a ferroelectric layer. In 1T1C (one-transistor-one capacitor) cell architectures, a cell capacitor is based on a ferroelectric material with a non-linear relationship between an applied electric field and the stored charge. An access transistor addresses and selects the respective cell capacitor. 1T (one-transistor) cell architectures are under investigation in order to store the data information in a ferroelectric gate dielectric without the need of a capacitor.

### SUMMARY

An integrated circuit as described herein includes a plurality of switching devices, wherein each switching device includes a gate dielectric that is capable of assuming at least a first and a second polarization state. The integrated circuit further includes an address circuit configured to control bit lines that are electrically coupled to first load terminals of a load path of the switching devices and a word line that is electrically coupled to gate electrodes of the switching devices. Thereby, the address circuit is configured to control a write cycle such that a first voltage drops over the gate dielectrics of selected ones of the switching devices and a second voltage drops over the gate dielectrics of non-selected ones of the switching devices. The first voltage suffices and the second voltage does not suffice to switch the gate dielectrics from the first to the second polarization state.

According to a method of operating an integrated circuit as described hereinafter, ferroelectric gate dielectrics of a plurality of switching devices are switched into a first polarization state. Subsequently, a write control signal is applied to gate electrodes of the switching devices, a write enable signal is applied to bit lines assigned to selected ones, and a write disable signal is applied to bit lines assigned to non-selected ones of the switching devices, wherein a first voltage is induced over the gate dielectrics of the selected ones and a second voltage over the gate dielectrics of the non-selected ones respectively. The first voltage suffices and the second voltage does not suffice to switch the gate dielectrics from the first into a second polarization state.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

The accompanying drawings are included to provide a further understanding of embodiments and are incorporated in and constitute a part of the specification. The drawings illustrate embodiments and together with the description serve to explain principles of the embodiments. Other embodiments and many of the intended advantages of embodiments will be readily appreciated as they become better understood by reference to the following detailed description. The elements of the drawings are not necessarily to scale relative to each other. Like reference numerals designate corresponding similar structures. Features of the various embodiments may be combined unless they exclude each other.

FIG. 1A illustrates a schematic cross-sectional view of a ferroelectric field effect transistor (FeFET) with a ferroelectric gate dielectric in a first polarization state for illustrating principles underlying the following embodiments.

FIG. 1B illustrates a schematic cross-sectional view of the FeFET of FIG. 1A with the ferroelectric gate dielectric in a second polarization state.

FIG. 1C illustrates a diagram schematically plotting a drain current versus a gate voltage for different polarization states of a ferroelectric gate dielectric of the FeFETs illustrated in FIGS. 1A and 1B.

FIG. 2A illustrates a schematic cross-sectional view of a further FeFET to which a write disable signal is applied at a first source/drain region for illustrating a write cycle in accordance with an operation method according to an embodiment of the invention.

FIG. 2B is a diagram schematically illustrating a voltage gradient along line B-B of FIG. 2A.

FIG. 2C illustrates a schematic cross-sectional view of a further FeFET, to which a write enable signal is applied at a first source/drain region for illustrating a write cycle in accordance with an operation method according to an embodiment of the invention.

FIG. 2D is a diagram schematically illustrating a voltage gradient along line D-D of FIG. 2C.

FIG. 3A illustrates a wiring scheme of a memory cell array with ferroelectric switching devices and source lines running perpendicular to bit lines in accordance with an embodiment of the invention.

FIG. 3B illustrates a schematic block diagram of an integrated circuit with the memory cell array of FIG. 3A according to an embodiment.

FIG. 3C illustrates a schematic plan view of the memory cell array of FIG. 3A.

FIG. 3D illustrates a schematic perspective view of a substrate portion for illustrating a method of manufacturing an integrated circuit with the memory cell array of FIG. 3A in accordance with an embodiment of the invention after recessing buried word lines.

FIG. 3E illustrates a schematic perspective view of the substrate portion of FIG. 3D after etching source line grooves.

FIG. 3F illustrates a schematic perspective view of a substrate portion including a portion of the memory cell array of FIG. 3A.

FIG. 4A illustrates a wiring scheme of a memory cell array with FeFETs and two groups of bit lines in accordance with another embodiment of the invention.

FIG. 4B illustrates a schematic block diagram of an integrated circuit with the memory cell array of FIG. 4A according to an embodiment.

FIG. 4C illustrates a schematic plan view of the memory cell array of FIG. 4A.

FIG. 4D illustrates a schematic perspective view of a substrate portion for illustrating a method of manufacturing an integrated circuit with the memory cell array of FIG. 4A in accordance with an embodiment of the invention after recessing buried word lines.

FIG. 4E illustrates a schematic perspective view of a substrate portion including a portion of the memory cell array of FIG. 4A according to an embodiment.

FIG. 5 are time charts for illustrating write signals in accordance with an operation method for floating body ferroelectric switching devices according to a further embodiment of the invention.

FIG. 6A illustrates a wiring scheme for a memory cell array with floating body ferroelectric switching devices with two separated gate dielectric portions and one common word line in accordance with another embodiment of the invention.

FIG. 6B illustrates a schematic block diagram of an integrated circuit with the memory cell array of FIG. 6A according to an embodiment.

FIG. 6C illustrates a schematic perspective view of a substrate portion for illustrating a method of manufacturing an integrated circuit with the memory cell array of FIG. 6A in accordance with another embodiment of the invention after forming a bottom insulator.

FIG. 6D illustrates a schematic perspective view of a substrate portion including a portion of the memory cell array of FIG. 6A according to a further embodiment.

FIG. 7A illustrates a wiring scheme for a memory cell array with floating body ferroelectric switching devices with two separated gate dielectric portions and two split word line portions in accordance with another embodiment of the invention.

FIG. 7B illustrates a schematic block diagram of an integrated circuit with the memory cell array of FIG. 7A according to another embodiment.

FIG. 7C illustrates a schematic perspective view of a substrate portion including a portion of the memory cell array of FIG. 7A according to a further embodiment.

FIG. 8A is a simplified flow chart of a method of operating an integrated circuit including a ferroelectric memory cell array.

FIG. 8B is a simplified flow chart of a method of manufacturing an integrated circuit including a ferroelectric memory cell array.

FIG. 9 is a simplified block diagram of an electronic system in accordance with another embodiment.

### DETAILED DESCRIPTION

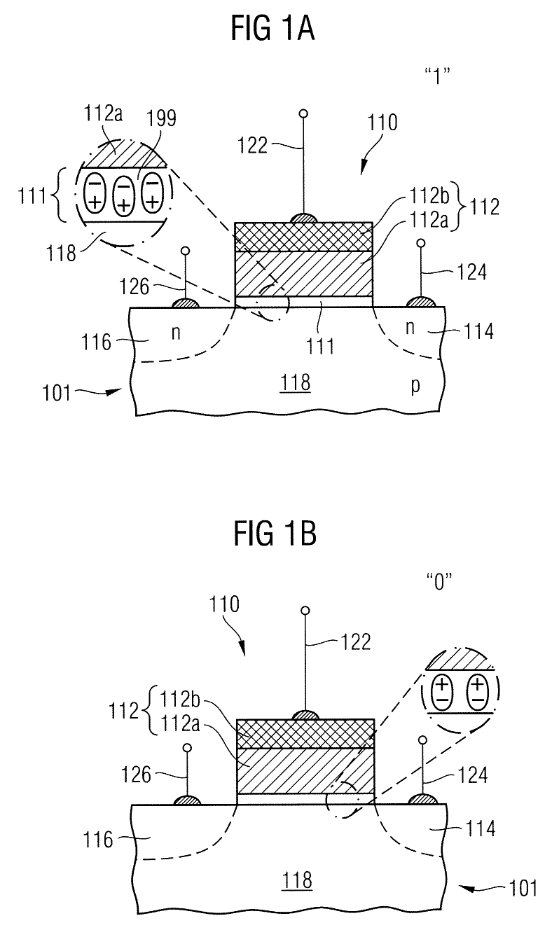

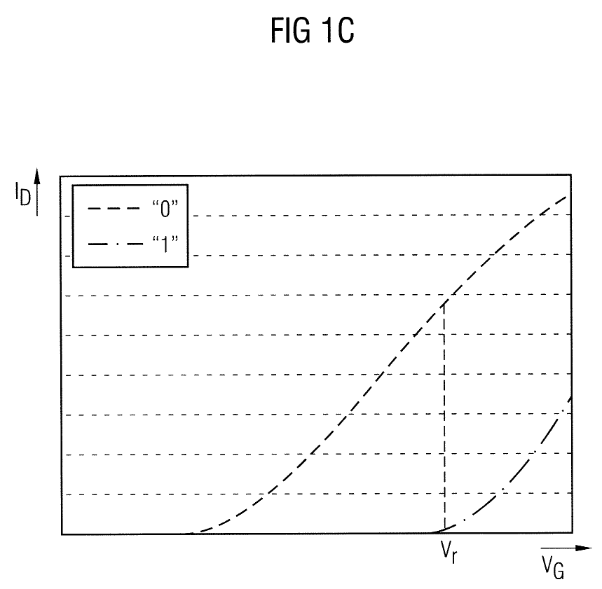

Referring to FIG. 1A, a gate dielectric 111 of a ferroelectric field effect transistor (FeFET) 110 is arranged between a conductive gate electrode 112 and a channel zone 118, which may be formed in a semiconductor structure 101 (e.g., a single-crystalline silicon layer). The gate dielectric 111 shows ferroelectric behavior and can be electrically polarized. The direction of the polarization may be switched between at least two states by applying an external electric field. The channel zone 118 may be intrinsic or may be an impurity region of a first conductivity type and is formed between a first source/drain region 114 and a second source/drain region 116, which are of a second conductivity type that is the opposite of the first conductivity type. According to the illustrated embodiment, the first conductivity type is the p-type and the second conductivity type is the n-type. According to other embodiments, the first conductivity type is the n-type and the second the p-type. The gate electrode 112 may include a first layer 112a that is in contact with the gate dielectric 111. The material of the first gate electrode layer 112a may be selected in view of a suitable work function. The gate electrode 112 may further include a high conductivity layer 112b with a higher conductivity than that of the first gate electrode layer 112a. The gate electrode 112 may be electrically coupled to a gate terminal 122. The first source/drain region 114 may be electrically coupled to a first source/drain terminal 124 and the second drain region 116 to a second source/drain terminal 126. Here and in the following, a first and a second structure are electrically coupled via a low-resistance path which may be, for example, a connection line and which may include other low-resistance structures like contacts, interface layers, forward biased junctions and others. In a primary polarization state, electric dipoles 199 in the ferroelectric gate dielectric 111 may be orientated with the positive pole towards the channel zone 118 and the negative pole towards the gate electrode 112. The primary polarization state may be defined as a logic “1”.

As illustrated in FIG. 1B, the FeFET 110 may assume a second logic state “0” corresponding to a secondary polarization state in which the electric dipoles in the ferroelectric gate dielectric 111 are orientated with the positive pole towards the gate electrode 112 and with the negative pole towards the channel zone 118. Both polarization states are stable. The polarization state may be switched by applying an electric field having an orientation contrary to that of the polarized dipoles and exceeding a coercitive field strength which may correspond to a voltage drop at the gate dielectric of several hundred mV.

According to FIG. 1C, the current polarization state may be read out by applying a suitable gate voltage VG at the gate electrode 112. The resulting electric field between the gate electrode 112 and the channel zone 118 superposes the electric field induced by the polarized ferroelectric gate dielectric 111. In the logic “0” state, the electric field resulting from the voltage applied to the gate electrode 112 and the electric field induced by the dipoles add up, whereas in the logic “1” state the electric field induced by the dipoles in the ferroelectric gate dielectric 111 reduces the electrical field induced by the biased gate electrode 112. As a consequence, a gate threshold voltage at which the FeFET becomes conductive is higher in the logic “1” state. At the same gate voltage VG, the FeFET 110 delivers a higher drain current ID in the logic “0” state than in the logic “1” state. A read voltage Vr, at which the information can be read out, may be selected as the highest gate voltage VG, at which the FeFET 110 is not yet conductive in the logic “1” state, for example.

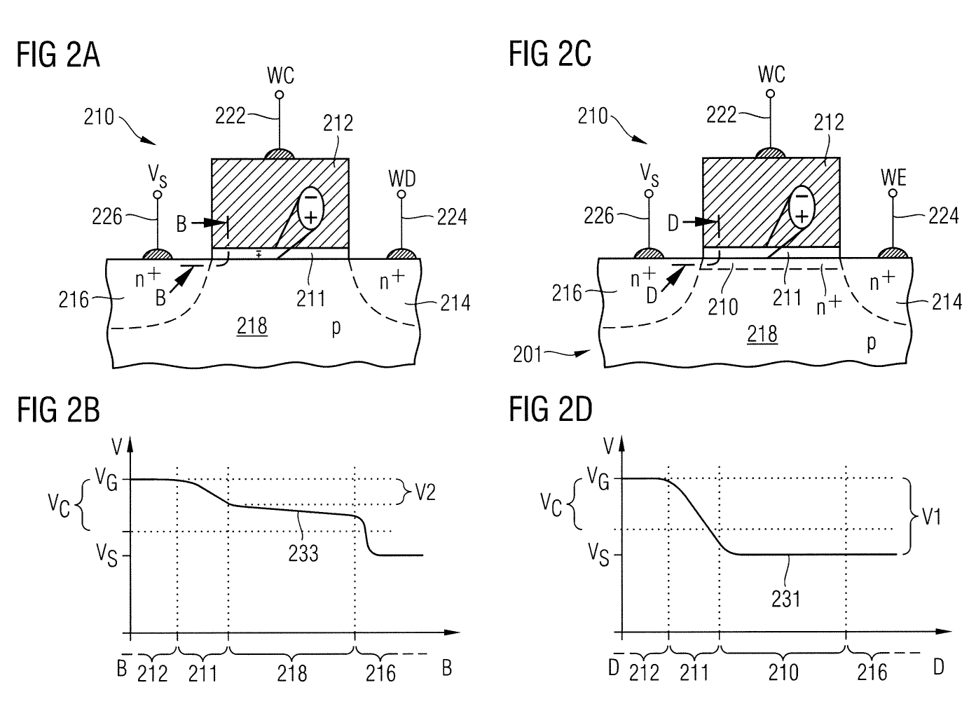

FIGS. 2A to 2D refer to an operation method for an integrated circuit with a memory cell array based on ferroelectric switching devices (e.g., FeFETs or ferroelectric thyristors (FeThyristors)) according to embodiments referring to switching devices with non-floating channel zones.

A channel zone 218 of a FeFET 210 as illustrated in FIG. 2A is formed between a first and a second source/drain region 214, 216 in a semiconductor structure 201. The charge carrier distribution in the channel zone 218 is controlled via a potential applied to a gate electrode 212, which is capacitively coupled with the channel zone 218 (body region) via an intermediate ferroelectric gate dielectric 211. A write cycle may be controlled via a first source/drain terminal 224 electrically coupled to the first source/drain region 214, a second source/drain terminal 226 electrically coupled to the second source/drain region 216 and a gate terminal 222 electrically coupled to the gate electrode 212. In a first phase of a write cycle, the ferroelectric gate dielectric 211 of a plurality of field effect transistors 210 associated to a common word line are switched into a first polarization state which may correspond to the primary polarization state corresponding to the logic “1”-state of FIG. 1A. The second source/drain terminals 226 may be tied to a fixed source potential VS (e.g., 1 V). The first polarization state may be induced by applying a negative gate voltage at the gate terminal 222, wherein, in the channel zone 218, the majority charge carriers accumulate along the interface to the gate dielectric 211 such that the gate voltage applied to the gate terminal 222 drops nearly completely over the gate dielectric 211. If the applied gate voltage exceeds the coercitive voltage, all FeFETs on the same word line switch to the logic “1”-state irrespective of the former state and irrespective of a potential applied to the first source/drain terminal 224.

In a second phase of the write cycle, those memory cells, in which a logic “0”-state is to be written, are selected by applying a write enable signal WE to the first source/drain terminal 224, whereas those memory cells, which should remain in the “1”-state, are deselected by applying a write disable signal WD to the first source/drain terminal 224. Approximately at the same time, a write control signal WC is applied to the gate terminals 222 of both the selected and the non-selected FeFETs. In accordance with an embodiment, the write signals are square pulse signals with amplitudes VWC, VWE, VWD applied approximately contemporaneously. According to other embodiments, the write control signal WC may be delayed or the write enable WE and write disable WD signals may be delayed.

As illustrated in FIG. 2B, the write disable signal WD and the write control signal WC in combination leave the FeFET 210 in a depletion state 233 or switch the FeFET 210 in a weak inversion state such that only a portion of the actual gate voltage VG (e.g., VWC) that is applied to the gate terminal 222 drops over the gate dielectric 211, wherein the partial voltage drop is lower than the coercitive voltage VC. Another portion of the gate voltage drops over the junction to the second source/drain region 216.

On the other hand, as illustrated in FIG. 2C, the write enable signal WE and the write control signal WC in combination may drive the FeFET 210 in sufficient strong inversion and can switch the FeFET 210 into a conductive state. The potential of an inversion channel 210 formed in the channel zone 218 along the interface to the gate dielectric 211 may be pinned to the potential of the first source/drain region 214. The voltage drop at the gate dielectric suffices is higher than a coercitive voltage of the gate dielectric and suffices to change the polarization state of the gate dielectric 211.

According to FIG. 2D, the write control signal WC and the write enable signal WE in combination induce a first voltage V1 over the gate dielectrics 211 of selected ones of the FeFETs 210, whereas according to FIG. 2B the write control signal WC and the write disable signal WD in combination induce a second voltage V2 over the gate dielectrics 211 of non-selected FeFETs 210. The first voltage V1 suffices and the second voltage V2 does not suffice to switch the gate dielectrics 211 into the second polarization state. The first voltage V1 may be equal to or greater than the coercitive voltage VC of the gate dielectrics 211 and the second voltage V2 is lesser than the coercitive voltage VC. The write control and write enable signals WC, WE in combination drive addressed FeFETs stronger into an inversion state than the write control and write disable signal WC, WD in combination. The inversion state is defined by the conductivity of a load path between the first and the second source/drain region 214, 216 which is more conductive in the inversion state than in the non-inversion state. The write control and the write disable signal WC, WD may leave the non-selected FeFETs in a depletion state or may drive them in a weak inversion state, wherein a voltage drop over the gate dielectric does not exceed the coercitive voltage VC. Equivalent considerations apply to ferroelectric thyristors, wherein the cathode terminal may be tied to the fixed potential VS and the write enable and write disable signals WE, WD may be applied to the anode terminal.

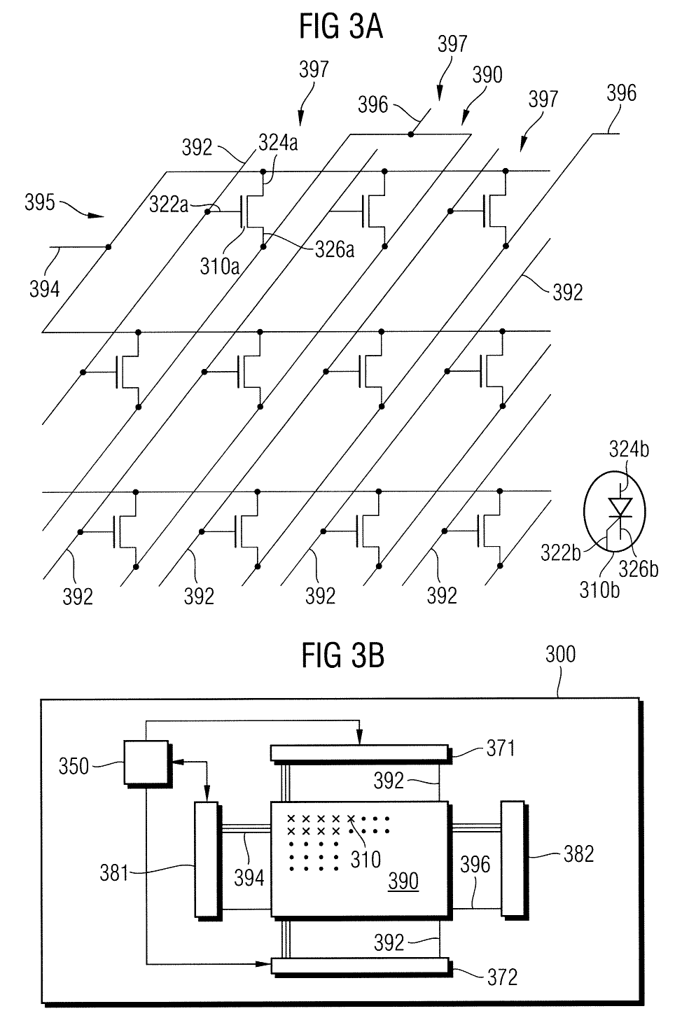

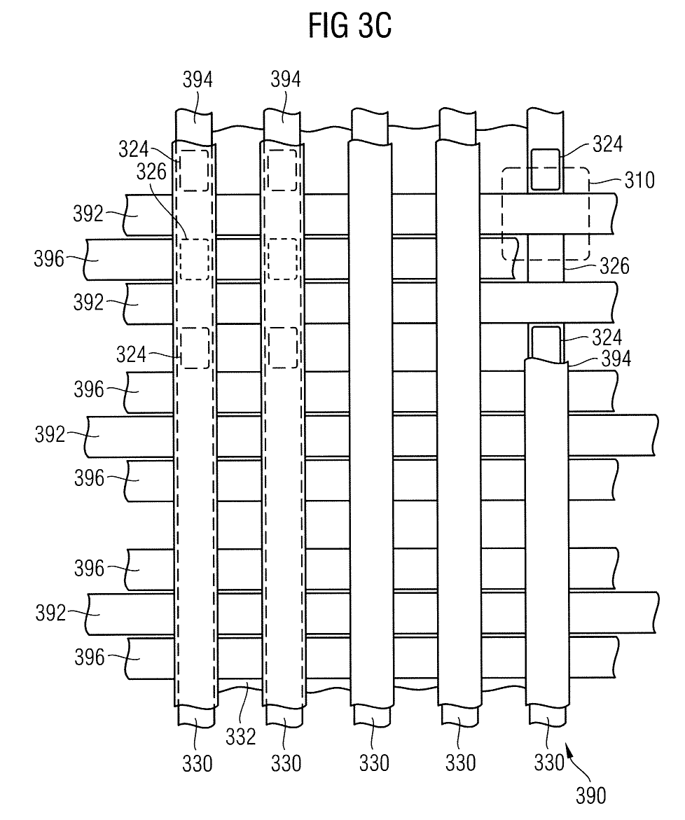

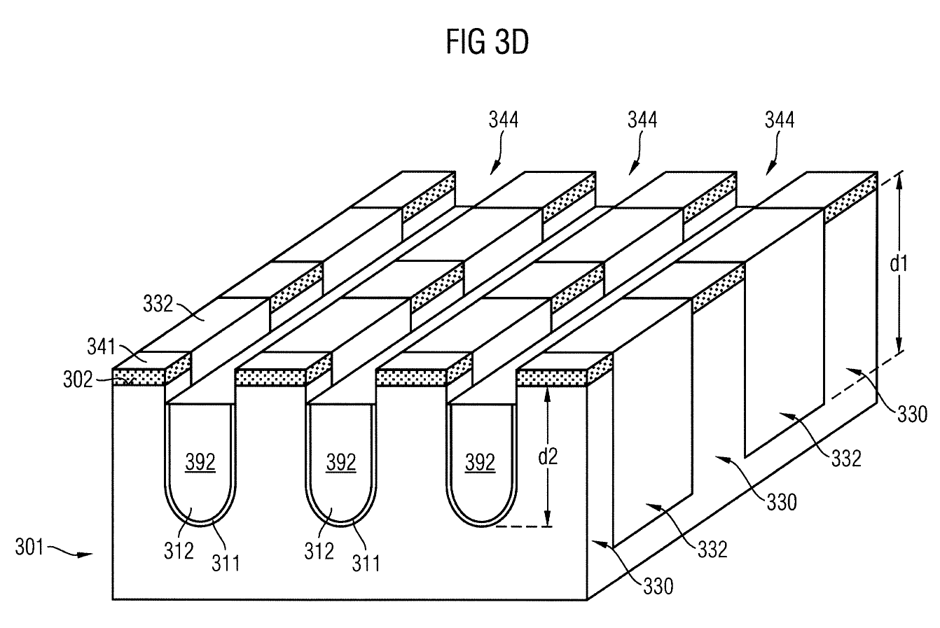

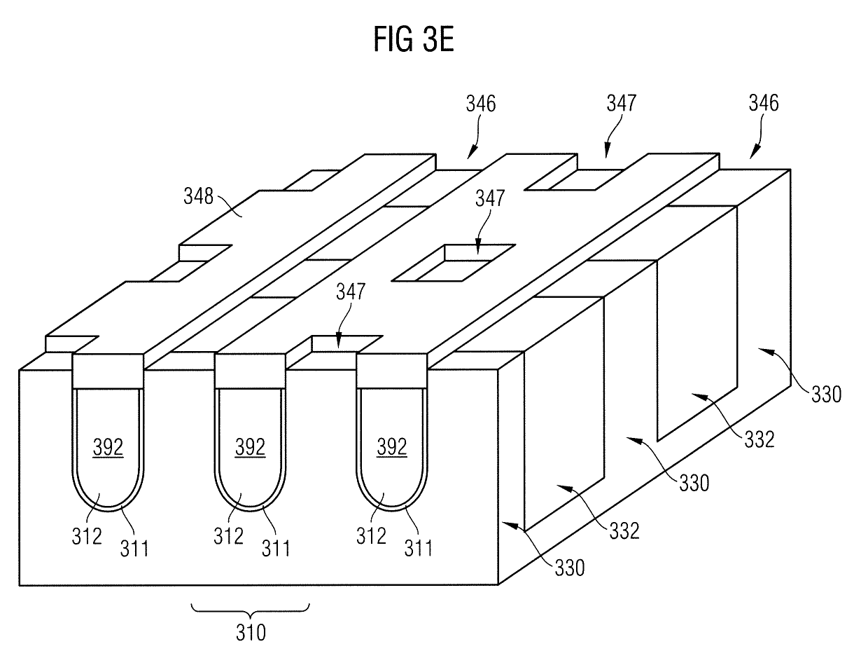

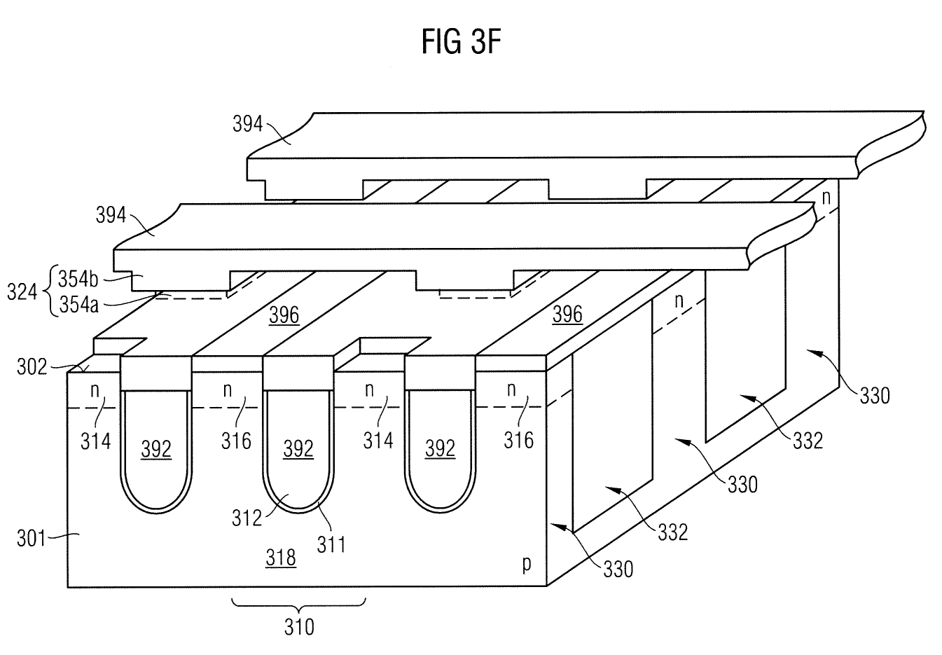

FIG. 3A refers to a memory cell array 390 based on 1T-memory cells of the FeFET-type 310a or the FeThyristor-type 310b as described above. For example, 1T-memory cells 310a of the FeFET-type may be arranged in a matrix with cell columns 397 and cell rows 395. The gate electrodes 322a of a group of memory cells 310a which are arranged along the same cell column 397 may be connected to one of a plurality of word lines 392, respectively. First source/drain terminals 324a of memory cells 310a arranged along the same cell row 395 may be connected to one of a plurality of bit lines 394 and second source/drain terminals 326a of the memory cells 310a may be connected to source lines 396.

In accordance with an embodiment, the source lines 396 may run parallel to the word lines 392. In accordance with other embodiments, the source lines 396 may run parallel to the bit lines 394. Each source line 396 may be assigned to the memory cells 310a assigned to one cell row 395 or to memory cells 310a assigned to one cell column 397 or to memory cells 310 assigned to a plurality of cell rows 395 or cell columns 397 (e.g., to two cell rows 395 or two cell columns 397). Each source line 396 may be connected to a voltage source, which may be configured to supply a constant voltage. The voltages supplied to the source lines 396 may deviate slightly from each other. In accordance with other embodiments, all source lines 396 of the memory cell array 390 are connected to each other to form a source line plate (e.g., common source plate), which may be connected with an output terminal of a voltage source configured to supply a constant voltage of about a few hundred mV, for example. In accordance with other embodiments, the memory cells 310a of the FeFET-type may be replaced with the memory cells 310b of the FeThyristor-type with the anodes 324b electrically coupled to the bit lines 394 and the cathodes 326b electrically coupled to the source lines 396. Each memory cell 310a, 310b may be addressed via two connection lines only (i.e., one bit line 394 and one word line 392).

FIG. 3B illustrates an integrated circuit 300 which may comprise a volatile or non-volatile memory device or a complex integrated circuit with embedded memory cells, for example a microprocessor, a microcontroller, an ASIC (application specific integrated circuit), a mixed signal device, or a chip card. An address circuit may include a control unit 350 connected with a first and a second word line driver 371, 372 and a bit line driver/sense circuit 381. The word lines 392 connect the first and the second word line driver circuits 371, 372 with the memory cell array 390. Each word line driver circuit 371, 372 is configured to drive write control signals for programming the logic “0” and “1” states. The bit line driver/sense circuit 381 is configured to drive the write enable and write disable signals on bit lines 394 connected with the memory cell array 390. The combined address circuit 350, 371, 372, 381 is adapted to switch selected ones of the memory cells 310 in the memory cell array 390 into a conductive inversion state so as to switch the polarization state in the course of the write cycle and may be further be adapted to approximately contemporaneously supply the write signals V_{W}, V_{WD}, V_{WE} as described with regard to FIGS. 2A to 2D to memory cells 310 associated to the same word line 392. The bit line driver/sense circuit 381 is further configured to drive binary output signals in dependence on the polarization state of gate dielectrics of the memory cells 310 associated to the respective bit line 394. A constant voltage source 382 is capable of supplying a potential (e.g., a fixed potential) to the memory cells 310 and is electrically coupled to the memory cells 310 via the source lines 396. The fixed source potential may be permanently supplied to the source lines 396. Each memory cell 310 may be addressed via the bit lines 394 and the word lines 392 only. This facilitates a low complex wiring scheme that enables small cell sizes and high memory densities. The combined address circuit 350, 371, 372, 381 may further be configured to control a hold state, in which the channel zones of the memory cells 310 are depleted and only a low electric field is effective over the gate dielectrics.

FIG. 3C illustrates a schematic plan view of a memory cell array 390 in accordance with another embodiment of the invention. Semiconductor bodies including channel zones and controllable load paths of memory cells 310 are formed in semiconductor lamellas which form active area lines 330. The active area lines 330 may be contiguous, straight lines, segmented lines or meandering lines with tilted and straight portions, which may follow each other in alternating order. Isolation structures 332 are arranged between neighboring active area lines 330 and insulate them from each other. Word lines 392 which cross the active area lines 330 may run perpendicular to the active area lines 330. In accordance with other embodiments, the word lines 392 may intersect the active area lines 330 at an angle of, for example, between about 30 degrees and about 60 degrees (e.g., 45 degrees). The word lines 392 may be arranged above the active area lines 330. In accordance with other embodiments, the word lines 392 are formed in trenches intersecting the isolation structures 332 and the active area lines 330 such that a lower edge of the word lines 392 is formed below an upper edge of the active area lines 330. Between each second pair of word lines 392, one source line 396 may be arranged that may bear directly on second load terminals of memory cells 310 assigned to two neighboring word lines 392, wherein source line contacts 326 are formed. The second load terminal may be the second source/drain region of a FeFET or the cathode region of a ferroelectric thyristor. Bit lines 394 may be arranged approximately in a vertical projection of the active area lines 330. Bit line contacts 324 connect first load terminals of each active area line 330 to the same bit line 394. The first load terminal may be the first source/drain region of a FeFET or the anode region of a ferroelectric thyristor. The layout enables a dense 4 F² cell array without buried source or bit lines and with relaxed overlay requirements, since the source lines 396 and the word lines 392 are assigned to different wiring layers.

FIG. 3D refers to a substrate portion of a semiconductor structure 301. The semiconductor structure 301 may be formed on a preprocessed work piece (e.g., a carrier substrate consisting of or including glass, plastic or a semiconductor). According to an embodiment, the carrier structure 301 may be a preprocessed single crystalline silicon wafer, a SiGe wafer, an A(III)-B(V) wafer or a silicon-on-insulator (SoI) and may include further doped and undoped sections, epitaxial semiconductor layers as well as further conductive and insulating structures that have previously been fabricated. A first hard mask layer, for example a silicon nitride layer, may be deposited on a horizontal main surface 302 of the structure 301. The first hard mask layer may be patterned to a stripe mask via lithography techniques which may include double patterning techniques. First grooves may be etched into the semiconductor structure 301. According to an embodiment, impurities may be implanted through the etched first grooves in order to form a p-type well or an n-type well within the semiconductor structure 301. Between the grooves and beneath the hard mask stripes, contiguous semiconductor lamellas form active area lines 330. Sidewalls of the active area lines 330 may be oxidized or a protective liner may be deposited on the exposed sidewalls of the active area lines 330. The first grooves may be filled with an insulator material, for example a doped or undoped silicon oxide (e.g., a boron-phosphorous silica glass, silicon dioxide, silicon nitride) or another dielectric material or a layered dielectric structure to form isolation structures 332 which insulate the active area lines 330 from each other.

A second hard mask layer may be deposited. The material of the second hard mask layer may facilitate a masked etch of both the material of the isolation structures 332 and the first hard mask material. The second hard mask material may be, for example, amorphous silicon, polycrystalline silicon or carbon. The second hard mask layer may be patterned to form a second hard mask by lithography techniques, which may include double patterning methods like pitch multiplication. The second hard mask includes line-shaped openings, which may run perpendicular to the active area lines 330. Second grooves 344, which may run perpendicularly to the active area lines 330, are etched into the isolation structures 332 and the active area lines 330. A bottom portion of the second grooves 344 may be rounded or bowed. The second grooves 344 may be shallower than the first grooves such that a first distance d1 between the main surface 302 and the lower edge of the isolation structures 332 is greater than a second distance d2 between the main surface 302 and the lower edge of the second grooves 344.

Subsequently, a ferroelectric liner is formed lining the second grooves 344, for example, by deposition of an amorphous layer (e.g., an amorphous layer with the main constituents hafnium and oxygen or zirconium and oxygen). A covering layer may be formed on the amorphous layer. The covering layer may be a dielectric, a conductive oxide, a metal or a metal compound. A deposition temperature of the covering layer may be lower than a crystallization temperature of the amorphous layer. Subsequently, the amorphous layer may be annealed to a temperature above its crystallization temperature in order to at least partly change its crystal state from amorphous to crystalline or partly crystalline resulting in a crystallized or partly crystallized oxide layer so as to form a ferroelectric gate dielectric 311 lining the second grooves 344. A further high conductive fill material may be deposited to form further portions of word lines 392. Sections of the word lines 392 crossing the active area lines 330 form gate electrodes 312. The fill material may be a metal or a metal compound (e.g., tungsten W, titanium nitride TiN, aluminum Al, or another material with an electric conductivity higher than that of tungsten). The gate dielectric 311 and the word lines 392 may be recessed such that an upper edge of the word lines 392 is formed below the main surface 302 and such that the word lines 392 are completely buried in the semiconductor structure 301.

FIG. 3D illustrates the word lines 392 intersecting perpendicularly stripe-shaped active area lines 330 and the isolation structures 332 in alternating order. Residuals of the first hard mask 341 cover the upper edges of the active area lines 330 between neighboring isolation structures 332 on the one hand and neighboring word lines 392 on the other hand.

According to FIG. 3E, another dielectric material or that of the isolation structures 332 may be deposited to fill the portions of the second grooves 344 above the word lines 392 up to the upper edge of the first hard mask residuals 341 such that a dielectric layer 348 surrounds the first hard mask residuals 341. Subsequently, a chemical mechanical polishing process may be performed that stops at the upper edge of the first hard mask residuals 341. A third hard mask layer may be deposited which is capable of masking an etch of both the material of the dielectric layer 348 and the first hard mask residuals 341 (e.g., amorphous silicon, polycrystalline silicon or carbon). The third hard mask layer may be used to form stripe-like third grooves 346 in the dielectric layer 348 between each second pair of word lines 392 in order to expose each second source/drain region along the active area lines 330. Subsequently, the remaining first hard mask residuals 341 may be removed to form dot-shaped fourth grooves 347 which expose one of the first source/drain regions respectively.

FIG. 3E illustrates the third and fourth grooves 346, 347 formed in the dielectric layer 348, wherein each third groove 346 exposes a plurality of second source/drain regions assigned to the same source line and wherein each fourth groove 347 exposes one single first source/drain region.

Referring to FIG. 3F, impurities may be implanted into upper regions of the active area lines 330 to form doped source/drain regions 314, 316 of FeFETs or the further doped regions of FeThyristors. Subsequently, the third and fourth grooves 346, 347 may be filled in the course of a damascene process by depositing a conductive fill material (e.g., tungsten, titanium or tantalum nitride or another material having a higher conductivity than tungsten) in order to form source lines 396 and first portions 354a of bit line contacts, and then performing a chemical-mechanical polishing process which stops at the upper edge of the dielectric layer 348. Then, an interlayer dielectric (e.g., a doped or undoped silicon oxide) may be formed via layer deposition and lithographic patterning such that the interlayer dielectric covers the source lines 396 and uncovers the first bit line contact portions 354a. Subsequently, a further dielectric layer may be deposited and bit lines 394 running perpendicular to the word lines 392 may be formed, for example, via a damascene technique.

FIG. 3F illustrates bit lines 394 which are connected to the first source/drain regions 314 of FeFETs 310 via bit line contacts 324, wherein each bit line contact 324 includes a first bit line contact portion 354a and an inter-dielectric landing pad 354b. The illustration of the inter-level dielectric between the source lines 396 and the bit lines 394 is omitted for the sake of clarity. The memory cells 310 may be based on a FeFET with a gate electrode 312 that is capacitively coupled to a channel zone 318 in the semiconductor structure 301 via the ferroelectric gate dielectric 311. The channel zone 318 connects the first and the second source/drain region 314, 316 in the semiconductor structure 301. In the conductive state of the memory cell 310, a current flow between the first and the second source/drain region 314, 316 depends on both the potential applied to the gate electrode 312 via the word line 392 and the polarization state of the ferroelectric gate dielectric 311.

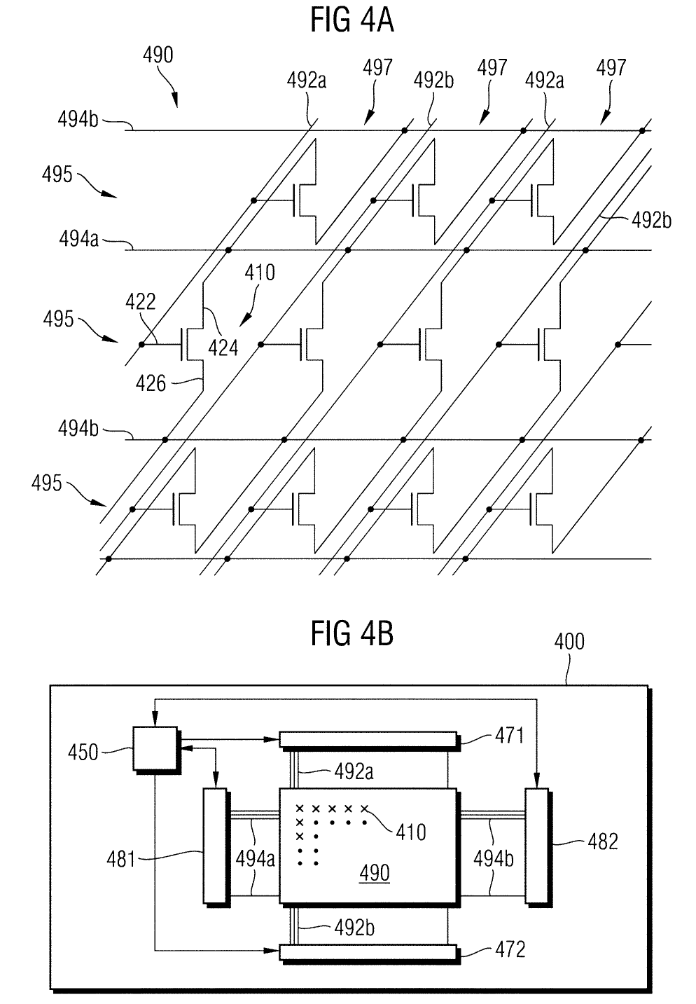

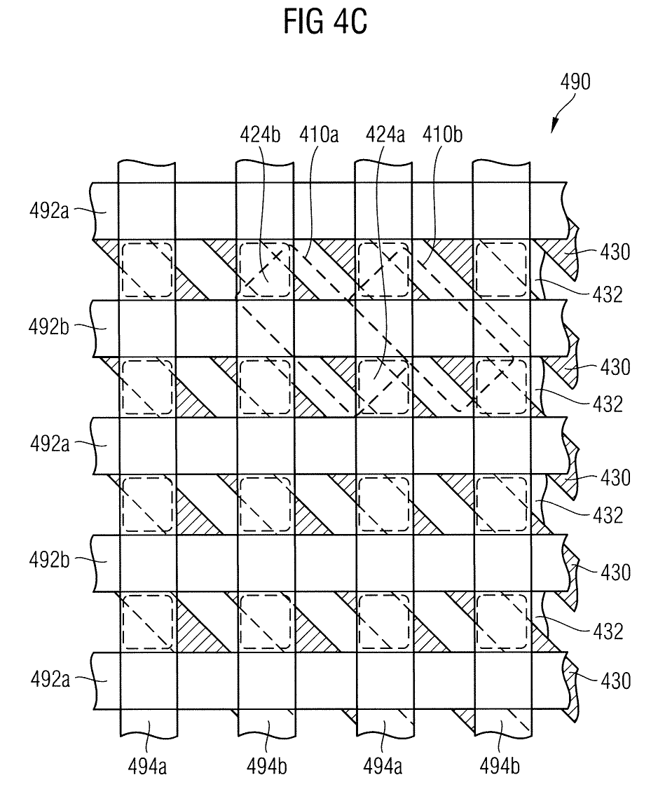

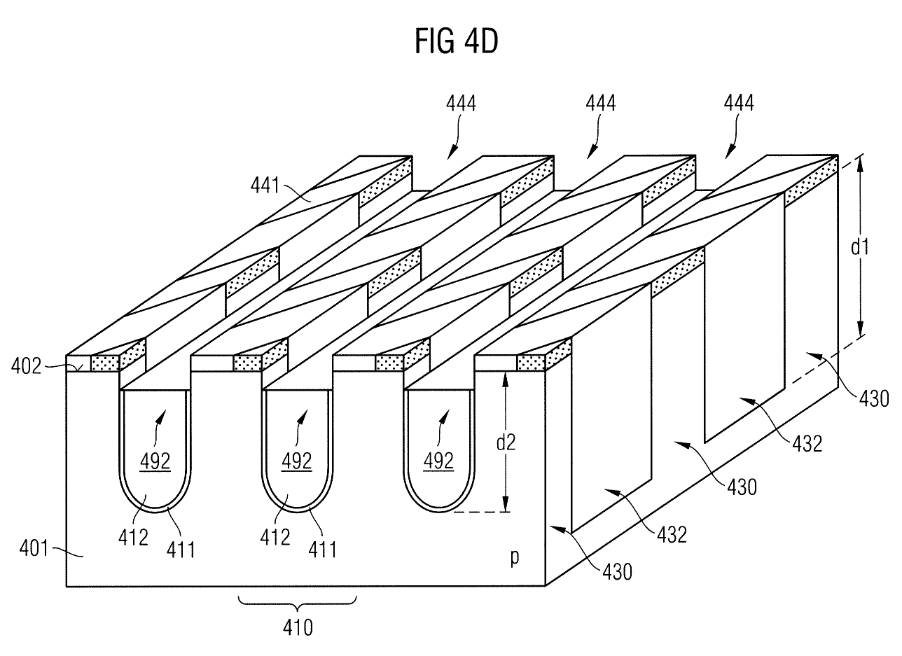

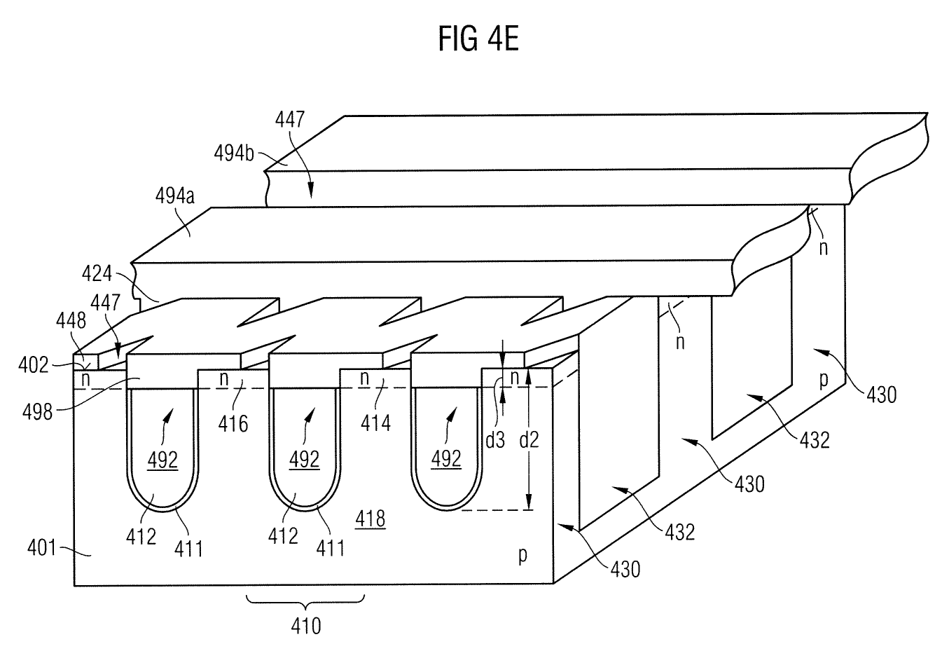

FIG. 4A refers to a memory cell array 490 in which both source/drain terminals 424, 426 of FeFET-based memory cells 410 are connected to first and second bit lines 494a, 494b that may be arranged in alternating order. The first bit lines 494a may be assigned to a first group of bit lines and the second bit lines 494b are assigned to a second group of bit lines. When the first group of first bit lines 494a is controlled as bit lines as described with reference to FIGS. 3A-3C, the second bit lines 494b of the second group of bit lines may be controlled as source lines as discussed with reference to FIGS. 3A-3C and vice versa.

The memory cells 410 may be arranged in a regular matrix. Groups of memory cells 410 associated to the same word line 492a, 492b may be arranged in cell columns 497. Groups of memory cells 410 assigned to the same bit line 494a, 494b may be arranged along two neighboring cell rows 495. The word lines 492a, 492b connect and electrically couple the gate terminals 422 of memory cells 410 of the respective cell column 497 with a word line driver circuit. Each first bit line 494a connects and electrically couples the first source/drain terminals 424 of two neighboring cell rows 495 to a bit line driver circuit and each second bit line 494b connects and electrically couples the second source/drain terminals 426 of two neighboring cell rows 495 with the bit line driver/sense circuit, wherein first and second bit lines 494a, 494b are arranged in alternating order.

FIG. 4B refers to an integrated circuit 400 that may include the memory cell array 490 with the memory cells 410 based on FeFETs as discussed with reference to FIG. 4A. Each memory cell 410 is connected to one of a plurality of first and one of a plurality of second bit lines 494a, 494b. The first bit lines 494a may be connected to a first bit line driver/sense circuit 481 and the second bit lines 494b may be connected to a second bit line driver/sense circuit 482. The first and second bit line driver/sense circuits 481, 482 are configured to sense a current and/or voltage signal which the selected memory cells 410 drive on the bit lines 494a, 494b during a read cycle and may face each other on opposing sides of the memory cell array 490. Further, each memory cell 410 may be associated to one of a plurality of first word lines 492a or to one of a plurality of second word lines 492b, wherein the first and the second word lines 492a, 492b may be arranged in alternating order. The first word lines 492a may be connected to a first word line driver circuit 471 and the second word lines 492a may be connected to a second word line driver circuit 472. The first and the second word line driver circuit 471, 472 may be arranged on opposing sides of the memory cell array 490. The first and second word line driver circuits 471, 472, the first and second bit line driver sense circuits 481, 482 and a control unit 450 may form an address circuit. The control unit 450 is configured to control the first and the second bit line driver/sense circuits 481, 482 such that one of the bit line driver/sense circuits 481, 482 supplies write enable and write disable signals to the respective first or second bit lines 494a, 494b and the other bit line driver/sense circuit 481, 482 contemporaneously supplies a constant voltage source signal to the respective bit lines 494a, 494b and vice versa.

In accordance with an embodiment, the first and second bit lines 494a, 494b may be associated to a first or a second sub-group of first or second bit lines 494a, 494b, wherein the respective bit line driver/sense circuit 481, 482 may be configured to drive alternatingly an inhibit or hold signal on the bit lines 494a, 494b associated to one of the sub-groups of first and second bit lines 494a, 494b, and contemporaneously a write enable signal, a write disable signal or a source voltage to the other sub-group in order to select one of the cell rows 495 associated to the same first or second bit line 494a, 494b. The inhibit or hold signal may correspond to the corresponding write enable signal or write disable signal transmitted via the other first or second bit line 494a, 494b associated to the non-selected cell row 495.

FIG. 4C illustrates a schematic plan view of a substrate portion with memory cells 410 of a memory cell array 490 in accordance with an embodiment corresponding, for example, to that of FIGS. 4A and/or 4B. The memory cells 410 may be FeFETs, the semiconductor body of which may be formed in straight semiconductor lamellas, which form active area lines 430. According to other embodiments, the active area lines 430 may be segmented or may include tilted and straight portions in alternating order. Isolation structures 432 are arranged between neighboring active area lines 430. Parallel first and second word lines 492a, 492b may be arranged in alternating order and run in a direction intersecting the direction in which the active area lines 430 run. An angle between the active area lines 430 and the word lines 492a, 492b may be between about 30 degrees and about 60 degrees (e.g., 45 degrees). The word lines 492a, 492b may be arranged above the active area lines 430 or may intersect the active area lines 430, such that a lower edge of the word lines 492a, 492b is below an upper edge of the active area lines 430. For example, the word lines 492a, 492b may be completely buried, wherein an upper edge of the word lines 492a, 492b is formed below an upper edge of the active area lines 430.

First and second bit lines 494a, 494b may be arranged above the word lines 492a, 492b and may run perpendicular to the word lines 492a, 492b. Between each pair of word lines 492a, 492b each bit line 494a, 494b is connected to one source/drain region formed in one of the active area lines 430. Each bit line 494a, 494b may be associated to exactly one of the active area lines 430. With regard to the word lines 492a, 492b, each bit line 494a, 494b is connected to two memory cells 410 controlled and addressed through the same word line 492a, 492b, wherein two memory cells 410 that are addressed via the same bit line 494a, 494b and the same word line 492a, 492b are associated to different active area lines 430. Bit line contacts 424a, 424b connect the first and second source/drain regions formed in the active area lines 430 with the respective bit lines 494a, 494b. For differentiating between two memory cells 410a, 410b associated to the same bit line 494a, 494b and to the same word line 492a, 492b, one of the associated bit lines 494a, 494b may transmit an inhibit or hold signal and the other a write enable, write disable or a read signal.

Though each memory cell 410 is addressed through three signals transmitted via the associated word line 492a, 492b and the associated first and second bit lines 494a, 494b, two address lines in a cross-point configuration suffice to address the memory cells 410. The cell array architecture is simple and facilitates high packaging densities.

FIGS. 4D and 4E refer to a method of manufacturing an integrated circuit with a memory cell array 490, for example, to a memory cell array as illustrated in FIGS. 4A and 4C.

According to FIG. 4D, a first hard mask layer (e.g., a silicon nitride layer) may be deposited on a main surface 402 of a semiconductor structure 401. The semiconductor structure 401 may be a single-crystalline silicon layer formed on a carrier substrate as described with reference to FIG. 3D. The first hard mask layer may be patterned to hard mask stripes via lithography techniques which may include double patterning methods like pitch multiplication to form a first hard mask. Using the hard mask stripes as an etch mask, first grooves may be etched into the semiconductor structure 401. The first grooves may have straight sidewalls or may taper with increasing depth. The first grooves expose approximately vertical sidewalls of active area lines 430 which are formed between the first grooves. Impurities may be implanted into the semiconductor structure 401 through the first grooves, for example, by out-diffusion or ion beam implant. For example, the semiconductor structure 401 may be p-doped. According to an embodiment, the vertical sidewalls of the active area lines 430 may be oxidized or a protective liner may be deposited that covers the vertical sidewalls of the active area lines 430. A first insulator material, for example, an un-doped or doped silicon oxide (e.g., a boron-phosphorous silica glass) may be deposited that fills the first grooves in order to form isolation structures 432 between the active area lines 430. A chemical mechanical polishing process may be performed which may stop on the upper edge of the first hard mask. A second hard mask material may be deposited, which facilitates a masked etch of the insulator structures 432, the first hard mask residuals and the semiconductor structure 401. The second hard mask layer is patterned by lithography techniques which may include double patterning methods (e.g., pitch multiplication) to form a second hard mask with stripes running tilted (e.g., at an angle of about 45 degrees) with respect to the active area lines 430. The second hard mask material may be, for example, amorphous silicon, polycrystalline silicon or carbon. Using the second hard mask as an etch mask, second grooves 444 may be etched through the insulator structures 432 and the active area lines 430. A ferroelectric liner and a conductive fill material may be deposited into the second grooves 444 and recessed as described with respect to FIG. 3E in order to form a ferroelectric liner and word lines 492 in the second grooves 444.

As illustrated in FIG. 4D, portions of the word lines 492 intersecting the active area lines 430 may be effective as gate electrodes 412 and portions of the ferroelectric liner extending along the active area lines 430 may be effective as gate dielectrics 411 of FeFET-based memory cells 410. The upper edge of the word lines 492 may be formed below the main surface 402 such that the word lines 492 are completely buried in the semiconductor structure 401. The second grooves 444 may be shallower than the isolation structures 432 such that a distance d1 between the lower edge of the isolation structures 432 and the main surface 402 is greater than a second distance d2 between the lower edge of the word lines 492 and the main surface 402. Between the word lines 492 rhombic first hard mask residuals 441 cover the active area lines 430.

Referring to FIG. 4E, a second insulator material may be deposited and recessed, for example, via a chemical mechanical polishing process stopping at the upper edge of the first hard mask residuals 441 of FIG. 4D in order to fill the second grooves 444 above the word lines 492. Then, the first hard mask residuals 441 may be removed selectively versus the first insulator material forming the isolation structures 432 and versus the second insulator material which forms a top oxide 498 above the word lines 492 so as to form third grooves 447 exposing horizontal surface portions of the active area lines 430. Impurities may be implanted into upper portions of the active area lines 430 adjoining to the main surface 402 in order to form first and second source/drain regions 414, 416, which may be n-doped impurity regions. Subsequently, bit lines 494a, 494b may be formed, for example, via a damascene method. An inter bit line dielectric may be deposited to fill the third grooves 447 temporarily. Stripe-shaped fourth grooves may be formed in the inter bit line dielectric, wherein the stripe-shaped fourth grooves may run perpendicular to the word lines 492 and may expose exactly one source/drain region 414, 416 of each active area line 430, respectively. In accordance with other embodiments, the fourth grooves may be filled with a sacrificial material or a conductive material in order to facilitate a self-aligned formation of bit line contacts 424 between the bit lines 494a, 494b and the source/drain regions 414, 416.

According to FIG. 4E, each memory cell 410 is based on a FeFET with a first and a second n-doped source/drain region 414, 416. Within the semiconductor structure 401 a p-doped channel zone 418 connects the first and the second source/drain region 414, 416. In accordance with other embodiments, the first and second source/drain regions 414, 416 may be p-doped and the channel zone 418 may be n-doped. A lower edge of the first and second source/drain regions 414, 416 may be approximately flush with an upper edge of the word lines 492 or may have a lower or greater distance to the main surface 402 than the upper edge of the word lines 492. A ferroelectric gate dielectric 411 is formed between the channel zone 418 and a gate electrode 412, which is a portion of the word line 492 between the first and second source/drain regions 414, 416. The second distance d2 between the lower edge of the word lines 492 and the main surface 402 is greater than a third distance d3 between the lower edge of the first and second source/drain regions 414, 416 and the main surface 402. The gate electrodes 412 are sections of word lines 492 connecting a plurality of the gate electrodes 412. A top insulator 498 may be formed between the main surface 402 and an upper edge of the word lines 492. An inter-level dielectric 448 which may include portions of the first and second insulator materials may cover the main surface 402. The first and the second insulator material may be the same. Rhombic fourth grooves 447 may be formed in the inter-level dielectric 448. The fourth grooves 447 may be filled with a conductive material to form rhombic bit line contacts 424. In accordance with other embodiments, the fourth grooves 447 are filled partially with a conductive material and an insulator material in the rest. In accordance with further embodiments, the fourth grooves 447 are completely filled with an insulator material (e.g., one of the first or the second insulator materials) or the bit lines 494a, 494b may bear directly on the main surface 402.

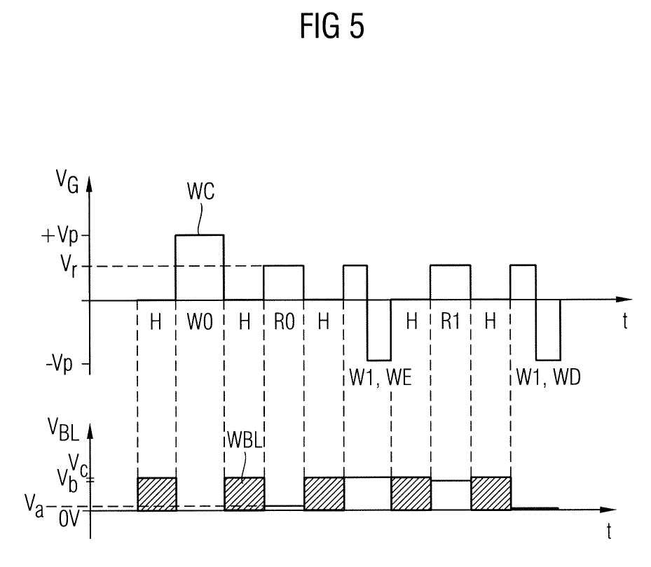

FIG. 5 illustrates time charts referring to a method of operating an integrated circuit with floating body ferroelectric switching devices (e.g., floating body FeFETs (FB FeFETs) or floating body FeThyristors (FB FeThyristors)). In the course of a write cycle, information is stored in the switching devices by forcing the ferroelectric gate dielectric of the switching device into one of at least two polarization states. In the course of a first write cycle phase, the ferroelectric gate dielectrics of a plurality of switching devices assigned to a common word line are switched into a first polarization state, for example the logic “0” state. In the course of a second write cycle phase, a write control signal is applied to the word line, a write enable signal is applied to bit lines assigned to selected ones and a write disable signal to bit lines assigned to non-selected ones of the switching devices such that a first voltage is induced over the gate dielectrics of the selected ones and a second voltage over the gate dielectrics of the non-selected ones, respectively, wherein the selected ones are switched into an inversion state in order to generate the first voltage. The first voltage is sufficient and the second voltage is not sufficient to change the polarization state of the gate dielectrics. The time charts refer to ferroelectric switching devices with floating p-doped channel zones (e.g., FB npn-FeFETs and FB pnpn-FeThyristors). Equivalent considerations apply to ferroelectric switching devices with floating n-doped channel zones (e.g., FB pnp-FeFETs and FB npnp-FeThyristors).

A first time chart in the upper half of FIG. 5 illustrates the signals applied to one of the word lines of a memory cell array, wherein the signals are represented by the gate voltage VG gradient. A second time chart in the lower half of FIG. 5 illustrates the signals applied to the bit lines of the memory cell array, wherein the signals are represented by the bit line voltage V_{BL} gradient. The memory cells and a bit line driver/sense circuit may alternatingly drive the signals on the bit lines, whereas the signals on the word line may be exclusively driven through a word line driver circuit.

During hold cycles H, a gate voltage V_{G} below a threshold voltage Vₜₕ of the memory cell is applied to the gate electrode, wherein the switching devices are left in a non-conductive off-state approximately independent of the bit line voltage. Since the channel zone under the gate electrode is depleted, a voltage between gate electrode and channel zone is lower than a coercitive voltage at which the polarization state may switch. The memory cells drive no signal on the bit lines which may float during the hold cycle.

In the course of read cycles R0, R1, a read voltage Vr is applied to the gate electrode. The read voltage Vr is higher than a threshold voltage of the switching device in at least one of the two polarization states but lower than the coercitive voltage. During the read cycles R0, R1 the addressed switching devices drive a low (R0) or a high level (R1) voltage Va, Vb or a current signal corresponding to the polarization state of the addressed gate dielectrics. At the read voltage Vr, the conductivity of load paths of switching devices in the first polarization state differs significantly from the conductivity of load paths of switching devices in the second polarization state. The signals on the bit lines are measured to sense the polarization state of switching devices assigned to the respective bit line. In accordance with another embodiment, a fixed voltage may be applied to the word line and the bit line voltage VBL may be altered (e.g., steadily increased) so as to sense the threshold voltage of the memory cells. According to yet another embodiment, at first the bit line voltage is set such that, once a memory cell has switched into the conductive state, the memory cell holds itself in the conductive state, for example due to a snap-back effect in an FeFET or due to an avalanche mechanism in an FeThyristor. Then, a gate voltage may be applied at which memory cells in the logic “0” state become conductive and memory cells in the logic “1” state remain non-conductive.

Each complete write cycle includes a first write cycle phase during which all memory cells associated to the same word line are switched into a first polarization state, which may be the secondary polarization state as defined with regard to FIG. 1A. In the course of a second write cycle phase, selected ones of the memory cells are switched into the primary polarization state and non-selected ones are left in the secondary polarization state. Different signals on the bit lines make the selection, whereas both the selected and the non-selected memory cells are addressed via the same word line signal.

In the course of the first write cycle phase W0, a positive program voltage +VP, which exceeds the coercitive voltage, may be applied to the gate electrodes, wherein the ferroelectric switching devices are switched into an inversion state, in which minority charge carriers are accumulated near the gate dielectric and form a conductive “channel” through the channel zone. A potential of the “channel” is pinned to a potential between that of the source line and that of the bit line, for example, approximately Va, such that the positive program voltage +VP approximately completely drops over the gate dielectric and switches the polarization state into the logic “0” state.

The second write cycle phase may start with a first period during which a sufficient potential difference is applied between bit lines and source lines associated to selected memory cells, the polarization state of which shall be switched to the logic “1” state, whereas a non-sufficient potential difference is applied between bit and source lines associated to non-selected memory cells, the polarization state of which shall maintain the logic “0” state. For example, a positive voltage Vc may be applied to the bit lines associated to selected memory cells and 0 Volt may be applied to the bit lines associated to non-selected memory cells, whereas the voltage on the source lines remains the same. A sufficient potential difference holds the memory cell in a conductive state once it has been switched into the conductive state, such that the respective memory cell is in a self-stabilizing inversion state. Further during the first period, a voltage exceeding the threshold voltage Vth for the logic “0” state (e.g., the read voltage Vr) may be applied to the gate electrodes of the selected and the non-selected memory cells such that the selected memory cells switch into the conductive state W1, WE and the non-selected memory cells remain in a non-conductive state or switch only in a less conductive state W1, WD.

In a second period of the second write cycle phase, after a settle time, after which all selected ones of the memory cells have reliably switched into the conductive state, a negative program voltage −VP may be applied to the gate electrodes of non-selected and selected ones of the memory cells. The selected ones of the memory cells remain in the conductive state. In case of FB npn-FeFETs, a parasitic bipolar npn-transistor may be switched on after a snap-back effect has occurred. A triggered FB FeThyristor may remain in the conductive state until it has been reset. In the conducting selected memory cells, the potential of the inversion channel is pinned approximately to the bit line potential such that a first voltage exceeding the coercitive voltage drops over the gate dielectric and causes the polarization state to switch from the “0” state to the “1” state. In the non-conducting non-selected memory cells, the potential of the channel zone depends on the relationship between the “greater” gate capacitance and the “smaller” body-to-source/drain capacitance such that a significantly lower second voltage, which is lower than the coercitive voltage, drops over the gate dielectric causing the non-selected memory cells to remain in the “0”-state.

During the first period, a write control signal applied to the word line and a write enable signal applied to the bit lines associated to selected ones of the memory cells in combination drive the addressed switching devices stronger into an inversion state than the write control signal and a write disable signal applied to the bit lines associated to non-selected ones of the memory cells in combination. In the inversion state, a load path between a first and a second load terminal of the switching device is more conductive than in a non-inversion state. According to an embodiment the write enable signal is a square pulse with the amplitude Vc.

In accordance with an embodiment, the ferroelectric switching device is a FB FeFET with a floating channel zone. The write control signal includes a first write control signal during the first period and a second write control signal during the second period following the first period. The first write control signal and the write enable signal in combination trigger an intrinsic bipolar transistor holding the FB FeFET in an inversion state during the second period, wherein a load path between a first and a second load terminal of the FB FeFET in the inversion state is more conductive than in a non-inversion state and the second write control signal changes the polarization state of the gate dielectrics of the selected ones of the field effect transistors.

In accordance with another embodiment, the ferroelectric switching devices are FB FeThyristors with a floating channel zone. The write control signal includes a first write control signal during a first period and a second write control signal during a second period following the first period. The first write control signal and the write enable signal in combination trigger the FB FeThyristor in conduction for the second period and the second write control signal changes the polarization state of the gate dielectrics of selected ones of the FB-FeThyristors.

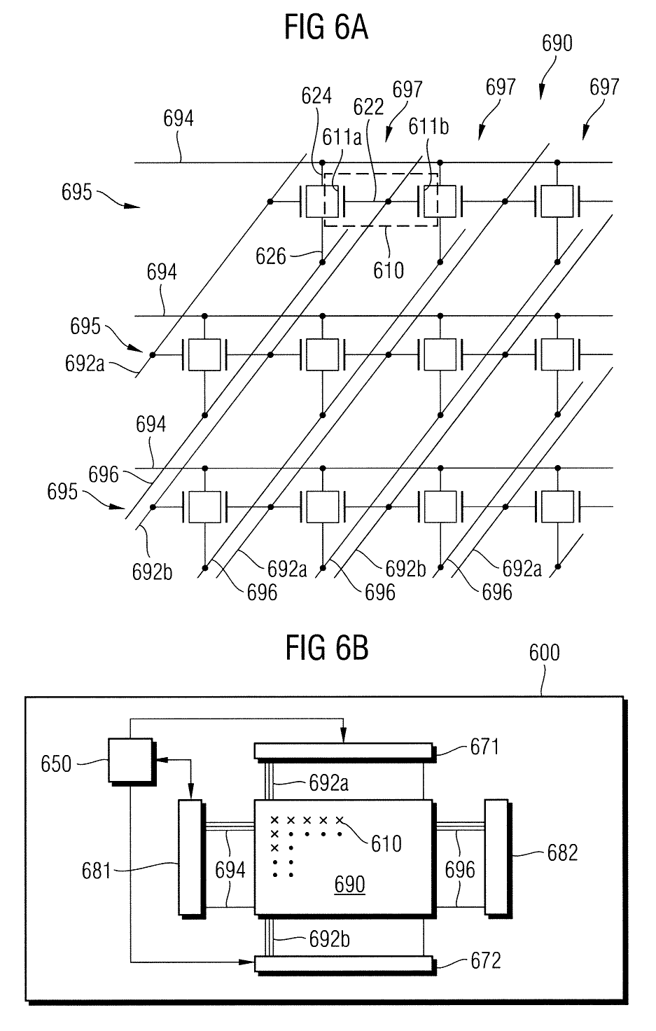

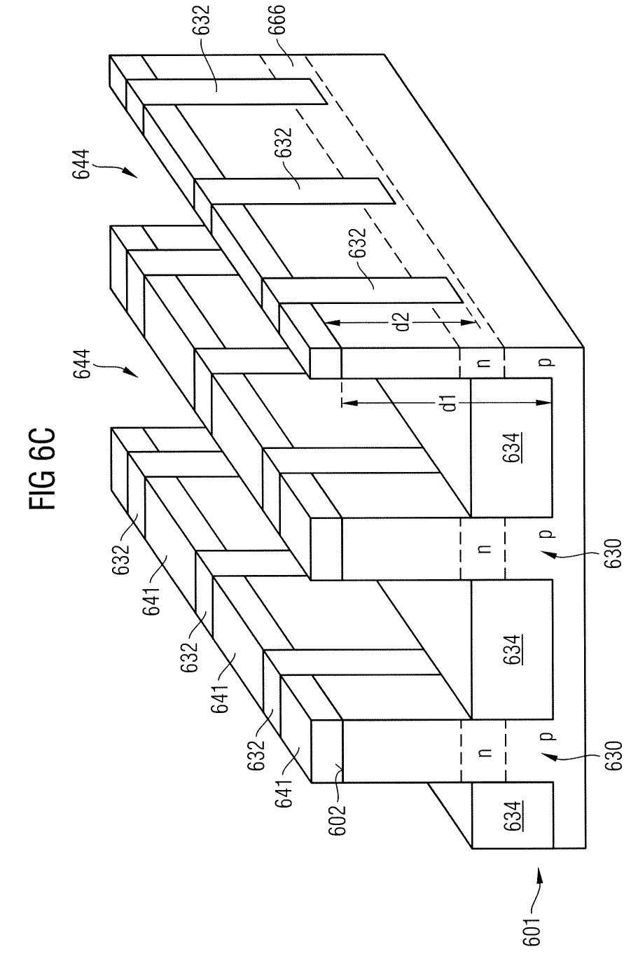

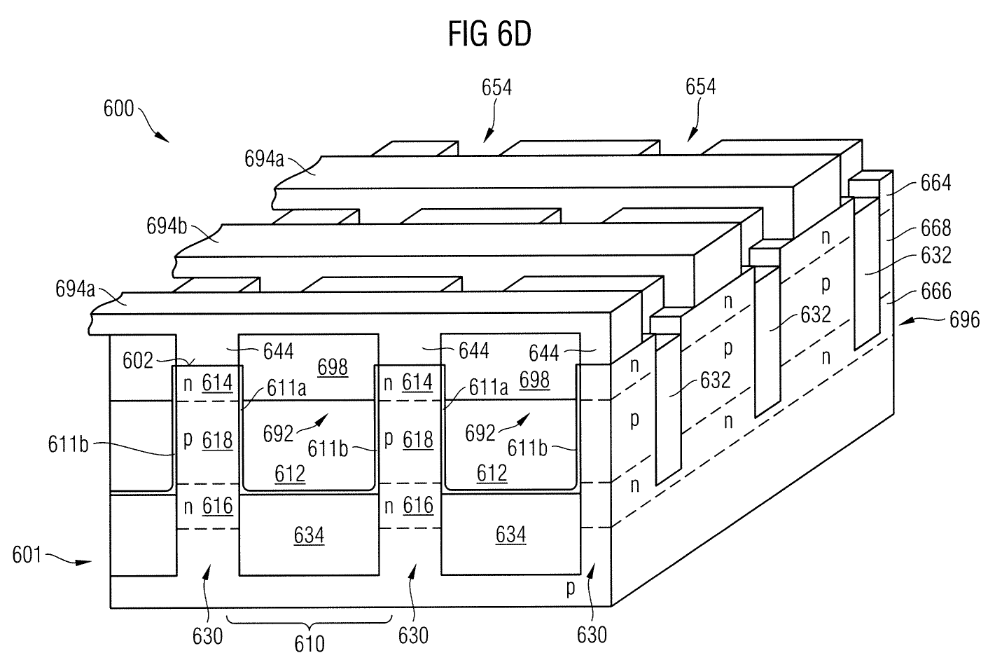

FIG. 6A refers to a memory cell array 690 with memory cells 610 based on floating body ferroelectric switching devices. A control terminal 622 of the respective memory cell 610 may be the gate electrode of an FB-FeFET or of an FB-Fe Thyristor. The memory cells 610 may be arranged in a regular matrix, wherein memory cells 610 associated to the same word line 692a, 692b are arranged in cell columns 697 and memory cells 610 associated to the same bit lines 694 are arranged in cell rows 695. First word lines 692a are associated to a first group of word lines and second word lines 692b are associated to a second group of word lines. The first and second word lines 692a, 692b may be arranged in alternating order. A source line 696 may run parallel to the bit line 694 or parallel to the word lines 692a, 692b, for example. The memory cells 610 may be FB FeFETs or FB FeThyristors. A load path between a first load terminal 624 and a second load terminal 626 of each memory cell 610 is arranged between an associated one of the bit lines 694 and an associated one of the source lines 696. The load terminals 624, 626 may be the first and second source/drain regions of a FB FeFET or an anode region and a cathode region of a FB FeThyristor. Each memory cell 610 includes two separated ferroelectric gate dielectrics 611a, 611b that may face each other on opposing sides of the respective word line 692a, 692b and that may be associated to the same bit line 694 and to the same source line 696 or to the same bit line 694 and to two neighboring source lines 696.

As illustrated in FIG. 6B, an integrated circuit 600 including a memory cell array 690 with memory cells 610 as illustrated in FIG. 6A additionally contains a combined address circuit including a first word line driver circuit 671, a second word line driver 672, a bit line driver/sense circuit 681 and a control unit 650 that is configured to control the word line and bit line driver/sense circuits 671, 672, 681. First word lines 692a connected the first word line driver 671 with gate terminals of a first group of memory cells 610 and second word line 692b connect and electrically couple a second word line driver circuit 672 to the gate terminals of further ones of the memory cells 610. The first and second word line driver circuits 671, 672 may face each other on opposing sides of the memory cell array 690. A source line driver circuit 682 may be a constant voltage source, which is adapted to supply a constant output voltage to source lines 696 which are connected to second load terminals of the memory cells 610. The bit lines 694 connect and electrically couple the bit line driver circuit 681 with the first load terminals of the memory cells 610. During a write cycle, both the first and the second gate dielectric 611a, 611b of the addressed memory cell 610 are forced to the same polarization state. During a read cycle, the polarization state of both gate dielectrics 611a, 611b contribute to an output signal.

FIG. 6C refers to a method of manufacturing an integrated circuit with a memory cell array as described with reference to FIGS. 6A and 6B in accordance with an embodiment. A first hard mask material is deposited on a carrier substrate with a semiconductor structure 601 as described with reference to FIG. 3D. The first hard mask material may be, for example, silicon nitride or any other material which may serve as an etch mask for an etch of the semiconductor material of the semiconductor structure 601 and an insulator material. Using lithography methods which may be combined with double patterning methods (e.g., pitch multiplication), a first hard mask with stripe-like openings is formed from the first hard mask layer. Using the first hard mask as an etch mask, stripe-like first grooves 644 are etched into the semiconductor structure 601. The first grooves 644 may have approximately vertical sidewalls or may taper with increasing depth. The first grooves 644 expose approximately vertical sidewalls of active area lines 630 which are formed between the first grooves 644. The vertical sidewalls may be covered by a protective liner, which may be a thermally grown oxide or a deposited liner (e.g., silicon nitride or silicon oxide liner). An insulator material, for example un-doped or doped silicon oxide (e.g., boron phosphorous silica glass) may be deposited to fill the first grooves 644. A chemical mechanical polishing process may be performed which may stop at the upper edge of the first hard mask residuals 641.

Via a further lithography process, for example, using a resist mask with stripe-like openings running perpendicular to the first grooves, the stripes of the first hard mask may be segmented to uncover and expose portions of the active area lines on a main surface 602 of the semiconductor structure 601. Using the segmented first hard mask lines as an etch mask, second grooves may be formed in at least the active area lines 630, wherein the second grooves segment the active area lines 630. The second grooves may be filled with a further material, for example, with a dielectric material against which the insulator structures 634 are selectively etchable. For example, the second grooves may be filled with silicon nitride to form insulator plugs 632 segmenting the active area lines 630. The second grooves may be shallower than the first grooves 644 such that a second distance d2 between a lower edge of the insulator plugs 632 and a main surface 602 is smaller than a first distance d1 between a lower edge of the first grooves 644 and the main surface 602. Then, an implant may be performed to form a buried impurity region 666 with a conductivity type opposite to that of the surrounding semiconductor structure 601. The buried impurity region 666 may be an n-doped region, wherein a lower edge of the buried impurity region 666 may be formed between a lower edge of the first grooves 644 and the lower edge of the insulator plugs 632 such that the buried impurity regions 666 of neighboring active area lines 630 are separated from each other and the buried impurity regions 666 of the same active area line 630 are connected to each other and form a conductive structure running along the respective active area line 630. In accordance with other embodiments, the buried impurity regions 666 extend below the first grooves 644 and form a buried plate.

The insulator structures filling the first grooves 644 may be recessed to form bottom insulators 634 in lower portions of the first grooves 644. An upper edge of the bottom insulators 634 may be approximately flush with an upper edge of the buried impurity regions 666 or may have a greater or a smaller distance to the main surface 602 than an upper edge of the buried impurity regions 666.

Referring to FIG. 6D, a suitable amorphous precursor material may be deposited and converted into a ferroelectric liner as described with reference to FIG. 3D. Subsequently, a high conductive material (e.g., titanium nitride, tungsten, aluminum or a material having a higher conductivity than tungsten) or a layered structure may be deposited to fill the first grooves 644 above the bottom insulators 634. The deposited material may be recessed to form word lines 692 in the grooves 644, wherein an upper edge of the word lines 692 may be formed below the main surface 602. A further insulator material (e.g., doped or undoped silicon oxide) may be deposited to fill the grooves 644 above the word lines 692 and a further chemical mechanical polishing process may be performed that stops at an upper edge of the first hard mask residuals 641 of FIG. 6C to form top insulators 698 above the word lines 692.

As illustrated in FIG. 6D, the height of the first hard mask residuals 641 of FIG. 6C determines a distance between the word lines 692 and the bit lines 694 formed later. Then, the first hard mask residuals 641 as illustrated in FIG. 6C are removed and a deglaze process may be performed. A further implant may be performed (e.g., an ion beam implant or an outdiffusion process) to form one or two upper impurity regions 664. Subsequently, bit lines 694 may be formed, for example, via a damascene process, in the course of which an inter bit line dielectric is deposited. Stripe-like grooves may be formed in the inter bit line dielectric and may be filled with a conductive material (e.g., doped silicon, titanium nitride, tungsten, or a material having a higher conductivity than tungsten) or a layered structure.

FIG. 6D refers to a portion of an integrated circuit 600 with vertically orientated, FB-FeFET based memory cells 610. Each memory cell 610 includes a first and a second ferroelectric gate dielectric 611a, 611b on opposing sides of a gate electrode 612. The gate electrodes 612 are portions of word lines 692 which are formed between neighboring active area lines 630. Buried impurity regions 666 may form second source/drain regions 616, which may be, for example, n-doped. The second source/drain regions 616 associated to the same active area line 630 are connected to each other and form source lines 696 running parallel to the word lines 692. First source/drain regions 614 may be formed in an upper impurity region 664 formed in an upper portion of the active area lines 630 adjoining the main surface 602. The first and second source/drain regions 614, 616 sandwich a floating channel zone 618 in-between. The second source/drain region 616, the floating channel zone 618 and the first source/drain region 614 are formed in this order in semiconductor pillars. Insulator plugs 632, which intersect the upper impurity layer 664 and a layer including the floating channel zone 618 but which may not necessarily intersect the bottom impurity layer 666, separate neighboring semiconductor pillars associated to the same active area line 630. Stripe-like structures including a bottom insulator 634, a word line 692 and a top insulator 698 are arranged between and may completely separate neighboring active area lines 630 from each other.

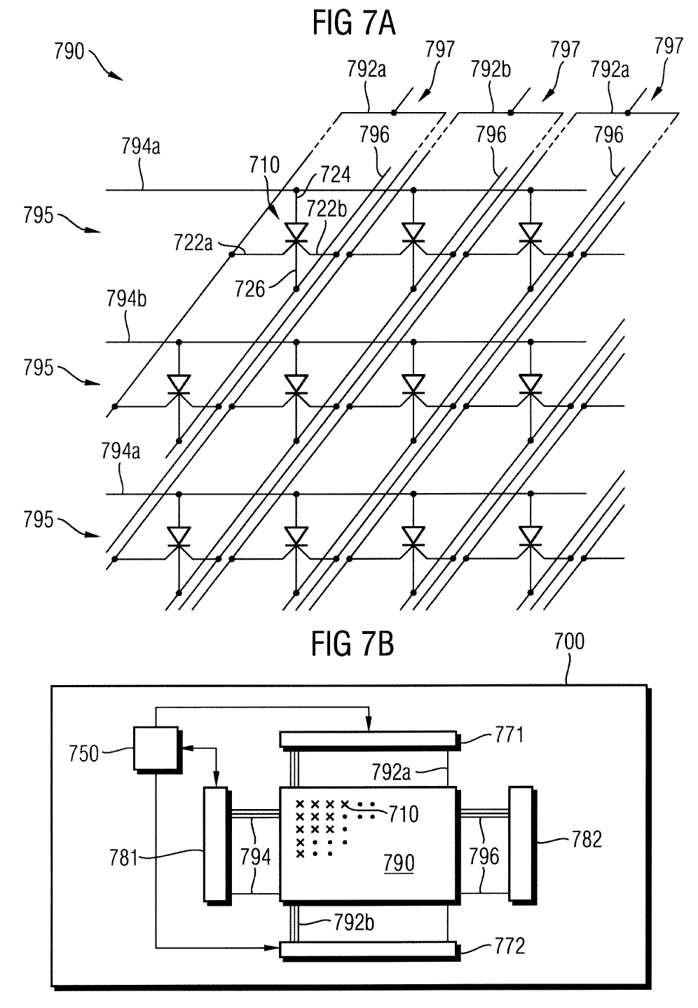

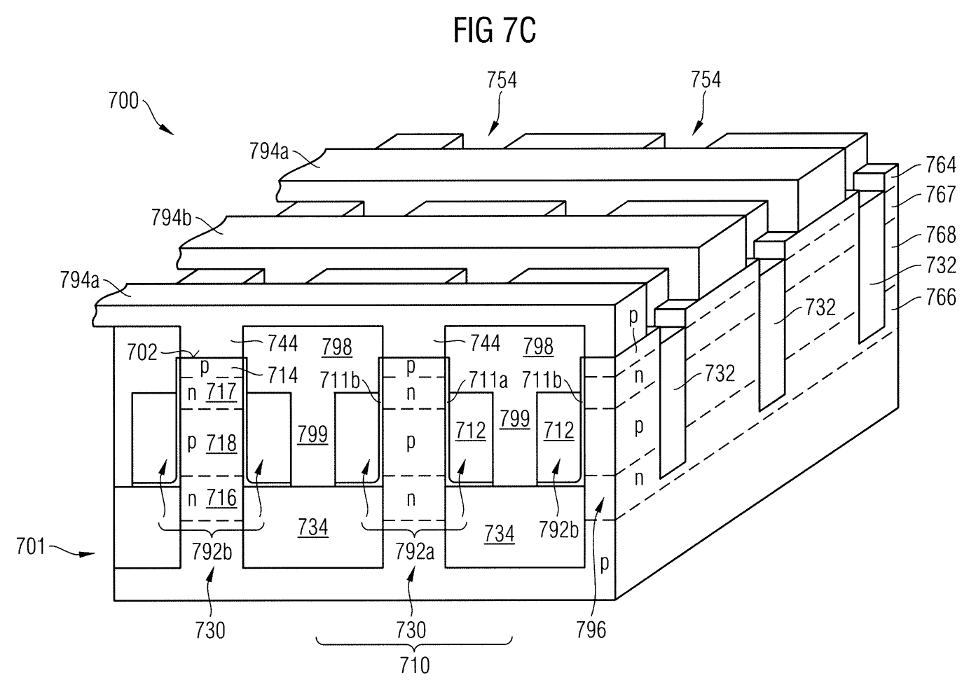

FIG. 7A illustrates a memory cell array 790 with memory cells 710 which may be based on FB FeFETs or on FB FeThyristors. The memory cells 710 may be arranged in a regular matrix. Memory cells 710 associated to the same word line 792a, 792b are arranged in cell columns 797 and memory cells 710 associated to the same bit lines 794a, 794b may be arranged in cell rows 795. First word lines 792a of a first group of word lines and second word lines 792b of a second group of word lines may be arranged in alternating order. Source lines 796 may run parallel or perpendicular to the bit lines 794a, 794b. A load path between a first load terminal 724 and a second load terminal 726 of each memory cell 710 is arranged between an associated one of the bit lines 794a, 794b and an associated one of the source lines 796. Two gate terminals 722a, 722b may be associated to a split gate electrode of an FB FeFET or an FB FeThyristor. The load terminals 724, 726 may correspond to the first and second source/drain regions of a FB FeFET or to an anode and a cathode region of a FB FeThyristor. Each word line 792a, 792b is split into two branches, and each memory cell 710 includes two separated ferroelectric gate dielectrics associated to one of the word lines branches, respectively.

According to FIG. 7B, an integrated circuit 700 including a memory cell array 790 with memory cells 710 as illustrated in FIG. 7A may additionally include a combined address circuit with a first word line driver circuit 771, a second word line driver 772, a bit line driver/sense circuit 781 and a control unit 750 that is configured to control the word line and bit line driver circuits 771, 772, 781. First word lines 792a connect and electrically couple the first word line driver circuit 771 with the gate terminals of memory cells 710 of the memory cell array 790 and second word lines 792b electrically couple and may connect the second word line driver circuit 772 with gate terminals of further memory cells 710. The first and second word line driver circuits 771, 772 may face each other on opposing sides of the memory cell array 790. A source line driver circuit 782 may be a constant voltage source that is capable of supplying a constant output voltage. Source lines 796 connect the source line driver unit 782 with the memory cells 710. The bit lines 794 connect the bit line driver circuit 781 to first load terminals of the memory cells 710. During a write cycle, both a first and a second gate dielectric are forced to the same polarization state. During a read cycle, the polarization state of both gate dielectrics contribute to an output signal.

A method of manufacturing an integrated circuit with a memory cell array 790 for example as described with reference to FIG. 7C may differ from the method as described with regard to FIGS. 6C and 6D in that the material of the word lines is deposited as a conformal layer which is thinner than the half width of the first grooves 644 of FIG. 6C and in an additional anisotropic spacer etch that separates the deposited word line material into two isolated word line portions or branches in each first groove 644. An inter word line dielectric may be formed during the formation of the top insulator 698 of FIG. 6D.

FIG. 7C illustrates a portion of an integrated circuit 700 with FB FeThyristor based memory cells 710 which are vertically orientated. Each memory cell 710 includes a first and a second ferroelectric gate dielectric 711a, 711b which face each other on opposing sides of an intermediate semiconductor pillar formed from a segment of an active area line 730. In accordance with the illustrated embodiment, the embedding semiconductor structure 701 is p-doped. Within each semiconductor pillar an n-doped cathode region 716, a floating p-doped channel zone 718, an n-doped floating avalanche region 717 and a p-doped anode region 714 may be formed in this order from the bottom up. According to other embodiments, the embedding semiconductor structure 701 and the floating channel zone 718 may be n-doped, whereas the cathode and the anode region are p-doped and change their function. In accordance with further embodiments, the buried doped region 766 forms a second source/drain region of a FB FeFET and one upper impurity region of the conductivity type of the buried impurity region 766 is formed in lieu of the anode and the avalanche regions 714, 717.

The cathode regions 716 associated to the same active area line 730 may be connected to each other to form source lines 796 running parallel to the word lines 792a, 792b. The anode and the cathode regions 714, 716 sandwich the avalanche regions 717 and the channel zones 718 in-between. Insulator plugs 732 segment the active area lines 730 and intersect the upper impurity layers 764, 767 and a body layer 768 including the floating channel zones 718 but do not necessarily intersect completely the buried impurity layers 766. Stripe-like structures including a bottom insulator 734, the word lines 792a, 792b, the inter word line dielectric 799 and a top insulator 798 separate neighboring active area lines 730. Between two neighboring active area lines 730 one pair of word line portions 792a, 792b associated to different word lines 792a, 792b are arranged. Word line portions 792a, 792b of the same word line face each other on opposing sides of the same active area line 730 and may be connected to each other outside the memory cell array 790.

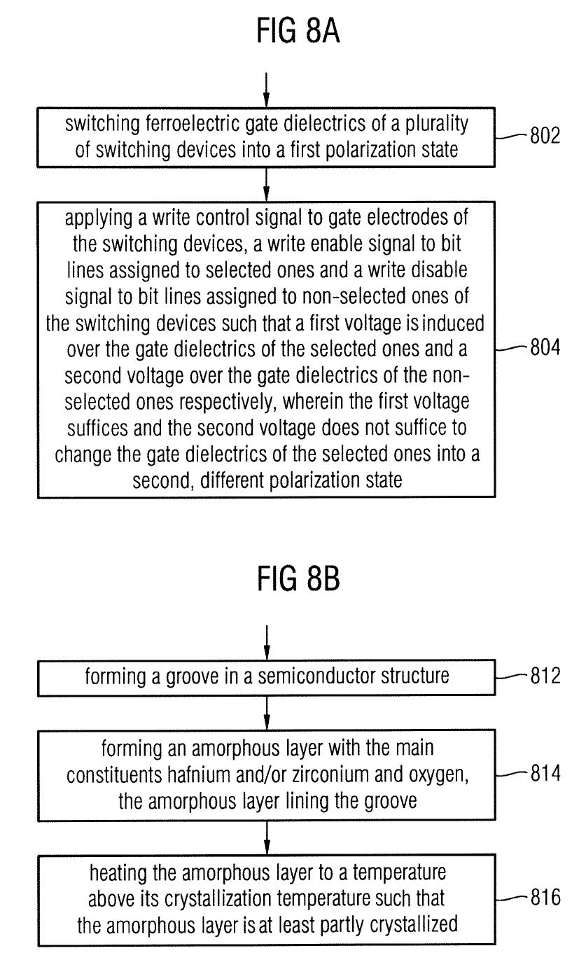

FIG. 8A refers to a method of operating an integrated circuit, wherein during a write cycle ferroelectric gate dielectrics of a plurality of switching devices are switched into a first polarization state (802). Thereafter, a write control signal is applied to gate electrodes of the switching devices, a write enable signal to bit lines assigned to selected ones and a write disable signal to bit lines assigned to non-selected ones of the switching devices such that a first voltage is induced over the gate dielectrics of the selected ones and a second voltage over the gate dielectrics of the non-selected ones respectively (804). The first voltage suffices and the second voltage does not suffice to change the gate dielectrics of the selected ones into a second, different polarization state.

FIG. 8B refers to a method of manufacturing an integrated circuit, wherein a groove is formed in a semiconductor structure (812). An amorphous layer with the main constituents hafnium Hf and/or zirconium Zr and oxygen O is formed and lines the groove (814). The amorphous layer is heated to a temperature above its crystallization temperature such that the amorphous layer (816) is at least partly crystallized.

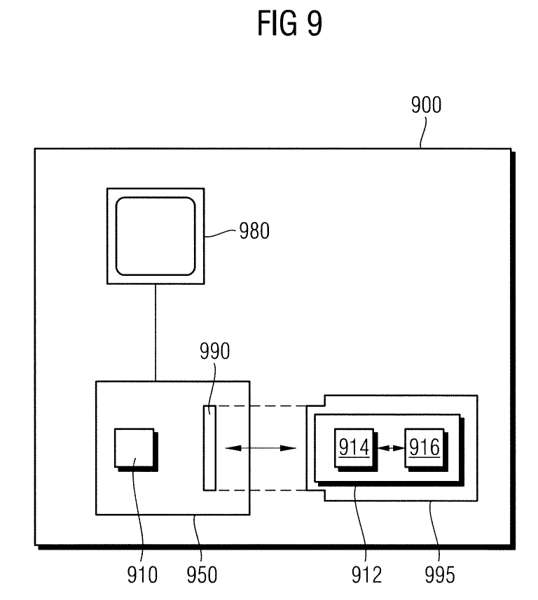

FIG. 9 schematically illustrates an electronic system 900 including a processor device 910 and an integrated circuit 912 that includes a plurality 914 of field effect transistors and an address circuit 916. Each field effect transistor includes a gate dielectric configured to assume at least a first and a second polarization state. The address circuit 916 is configured to control bit lines electrically coupled to first source/drain electrodes and to control a word line electrically coupled to gate electrodes of the field effect transistors such that, during a write cycle, a first voltage is induced at the gate dielectrics of selected ones and a second voltage is induced at the gate dielectrics of non-selected ones of the field effect transistors. The first voltage suffices and the second voltage does not suffice to switch the gate dielectrics from the first to the second polarization state.

The electronic system 900 may include an electronic sub-assembly 995 configured to be contacted at an interface and an interface 990 configured to electrically contact the electronic sub-assembly 995. The interface 990 may be a socket or a connector, for example. The integrated circuit 912 may, for example, be an interface circuit with embedded memory, a controller chip with embedded memory, an application specific integrated circuit with embedded memory or a memory chip mounted on the electronic sub-assembly 995. In accordance with other embodiments, the integrated circuit 912 is mounted on the same carrier as the processor device 910.

The processor device 910 may be mounted on a further sub-assembly or on a mother board 950 of the electronic system 900. The processor device 910 may be configured to process data received and/or transmitted from or via the electronic sub-assembly 995. The electronic system 900 may include further components (e.g., a display 980 for displaying data).

The electronic system 900 may, for example, be a computer (e.g., a personal computer or a notebook), a server, a router, a game console (e.g., a video game console or a portable video game console), a graphic card, a personal digital assistant, a digital camera, a cell phone, an audio system, a video system, a memory system (e.g., a USB stick or a solid state drive).

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. An integrated circuit, comprising:
a plurality of field effect transistors, each field effect transistor comprising a gate dielectric configured to assume at least a first and a second polarization state; and
an address circuit configured to control bit lines electrically coupled to first source/drain electrodes and a word line electrically coupled to gate electrodes of the field effect transistors such that during a write cycle a source potential is applied to second source/drain electrodes of the field effect transistors, a first voltage is induced at the gate dielectrics of selected ones and a second voltage is induced at the gate dielectrics of non-selected ones of the field effect transistors, wherein the first voltage suffices and the second voltage does not suffice to switch the gate dielectrics from the first to the second polarization state.

2. The integrated circuit of claim 1, wherein the address circuit is configured to switch the selected ones of the field effect transistors into a conductive inversion state such that the polarization state is switched in the course of the write cycle.

3. The integrated circuit of claim 1, further comprising:
a sense circuit electrically coupled to one of the bit lines and configured to drive a binary output signal in dependence on the polarization state of the gate dielectric of one of the field effect transistors associated to the respective bit line.

4. The integrated circuit of claim 1, wherein the address circuit is configured to contemporaneously supply a write enable signal to first ones of the bit lines associated to the selected ones and a write disable signal to second ones of the bit lines associated to the non-selected ones of the field effect transistors during the write cycle.

5. The integrated circuit of claim 1, further comprising:
a further plurality of field effect transistors assigned to the bit lines and further word lines, wherein the address circuit is further configured to drive the further word lines and the bit lines such that the first voltage is applied to gate dielectrics of further selected ones and is not applied to gate dielectrics of further non-selected ones of the field effect transistors.

6. The integrated circuit of claim 5, wherein channel zones of the field effect transistors are electrically coupled to a constant voltage source configured to supply a constant voltage.

7. The integrated circuit of claim 5, wherein channel zones of the field effect transistors are floating channel zones.

8. The integrated circuit of claim 7, wherein the first voltage is induced after the selected ones of the field effect transistors have been switched into a conducting and self-stabilizing inversion state.

9. The integrated circuit of claim 1, wherein the first voltage is induced during a conducting inversion state of the selected ones of the field effect transistors.

10. The integrated circuit of claim 9, wherein second source/drain regions of the pluralities of field effect transistors are connected to a common source plate.

11. The integrated circuit of claim 9, wherein:
the first source/drain regions of the field effect transistors are electrically coupled to first bit lines;
second source/drain regions of the field effect transistors are electrically coupled to second bit lines arranged in alternating order with the first bit lines; and
the address circuit is configured to alternately drive the first and second bit lines.

12. The integrated circuit of claim 9, wherein:
the bit lines run perpendicular to the word lines; and
the first and second source/drain regions of pluralities of field effect transistors are oriented along semiconductor lamellas running tilted to both the bit lines and the word lines.

13. The integrated circuit of claim 1, wherein second source/drain regions of the field effect transistors are electrically coupled to at least one source line.

14. The integrated circuit of claim 1, wherein each word line is arranged in a word line trench formed in a main surface of a semiconductor substrate.

15. An integrated circuit, comprising:
pluralities of thyristors, each thyristor comprising a gate dielectric configured to assume at least a first and a second polarization state; and
an address circuit configured to control bit lines electrically coupled to anode regions and a word line electrically coupled to gate electrodes of a first plurality of the thyristors such that during a write cycle a first voltage is induced at the gate dielectrics of selected ones and a second voltage at the gate dielectrics of non-selected ones of the thyristors, wherein the first voltage suffices and the second voltage does not suffice to switch the gate dielectrics from the first to the second polarization state.

16. The integrated circuit of claim 15, wherein the address circuit is configured to switch the selected ones of the thyristors into a conducting inversion state such that the polarization state is switched in the course of the write cycle.

17. The integrated circuit of claim 15, wherein channel zones of the thyristors are floating channel zones.

18. The integrated circuit of claim 15, wherein the first voltage is induced after the selected ones of the thyristors have been switched into a conductive and stable inversion state.

19. A method of operating an integrated circuit, the method comprising:
switching ferroelectric gate dielectrics of a plurality of switching devices into a first polarization state; and thereafter,
applying a write control signal to gate electrodes of the switching devices, a write enable signal to bit lines assigned to selected ones of the switching devices and a write disable signal to bit lines assigned to non-selected ones of the switching devices such that a first voltage is induced over the gate dielectrics of the selected ones and a second voltage is induced over the gate dielectrics of the non-selected ones, respectively, wherein the first voltage suffices and the second voltage does not suffice to change the gate dielectrics of the selected ones into a second, different polarization state.

20. The method of claim 19, wherein the first voltage is equal to or greater than and the second voltage is less than a coercitive voltage of the gate dielectrics.

21. The method of claim 19, wherein the write control and write enable signals in combination drive the addressed switching devices stronger into an inversion state than the write signal and the write disable signal in combination, wherein a load path between a first and a second load terminal of the switching device in the inversion state is more conductive than in a non-inversion state.

22. The method of claim 19, further comprising:
applying a read voltage to the gate electrodes, wherein at the read voltage the conductivity of load paths of switching devices of the first polarization state differs from the conductivity of load paths of switching devices of the second polarization state; and
measuring signals on one of the bit lines to sense the polarization state of switching devices assigned to the respective one of the bit lines.

23. The method of claim 19, wherein the write signals are applied approximately contemporaneously and overlap temporarily.

24. The method of claim 19, wherein:
first load terminals of the switching devices are electrically coupled to first bit lines and second load terminals are electrically coupled to second bit lines arranged in alternating order with the first bit lines; and
the write enable and write disable signals are sequentially applied to the first and second bit lines.

25. The method of claim 19, further comprising:
supplying a constant voltage to channel zones of the switching devices, wherein switching the gate dielectrics of the plurality of switching devices into the first polarization state comprises applying a first program signal to the gate electrodes such that the switching devices are driven into an accumulation state in which majority carriers are accumulated in the channel zones next to the gate dielectrics.

26. The method of claim 19, wherein:
each switching device is a floating body field effect transistor comprising a floating channel zone;
the write control signal comprises a first write control signal during a first period and a second write control signal during a second period following the first period;
the first write control signal and the write enable signal in combination trigger an intrinsic bipolar transistor holding the field effect transistor in an inversion state during the second period, wherein a load path between a first and a second load terminal of the switching device in the inversion state is more conductive than in a non-inversion state; and
the second write control signal changes the polarization state of the gate dielectrics of selected ones of the field effect transistors.

27. The method of claim 19, wherein:
each switching device is a thyristor comprising a floating channel zone;
the write control signal comprises a first write control signal during a first period and a second write control signal during a second period following the first period;
the first write control signal and the write enable signal in combination trigger the thyristor in conduction for the second period; and
the second write control signal changes the polarization state of the gate dielectrics of selected ones of the thyristors.

28. A method of manufacturing an integrated circuit, the method comprising:
forming a groove in a semiconductor structure;
forming an amorphous layer with the main constituents hafnium and/or zirconium and oxygen, the amorphous layer lining the groove; and
heating the amorphous layer to a temperature above its crystallization temperature such that the amorphous layer is at least partly crystallized.

29. The method of claim 28, further comprising:
forming a covering layer on the amorphous layer prior to heating the amorphous layer.

30. An electronic device, comprising:
a processor device; and
an integrated circuit, including:
a plurality of field effect transistors, each field effect transistor comprising a gate dielectric configured to assume at least a first and a second polarization state; and
an address circuit configured to control bit lines electrically coupled to first source/drain electrodes and a word line electrically coupled to gate electrodes of the field effect transistors such that, during a write cycle, a first voltage is induced at the gate dielectrics of selected ones and a second voltage is induced at the gate dielectrics of non-selected ones of the field effect transistors, wherein the first voltage suffices and the second voltage does not suffice to switch the gate dielectrics from the first to the second polarization state.

31. The electronic device of claim 30, wherein the processor device is configured to process data received and/or transmitted from or via a subassembly including the integrated circuit.
